(19) United States
(12) Patent Application Publication
(10) Pub. No.: US 2024/0327975 A1
(43) Pub. Date: Oct. 3, 2024

(54) TRIBOLOGICAL COMPOSITES

(71) Applicant: University of Leeds, Leeds (GB)

(72) Inventors: Liuquan Yang, Leeds, Yorkshire, (GB); Nik Roselina BINTI NIK ROSELEY, Leeds, Yorkshire (GB); Robbie Nathan BRITTAIN, Leeds, Yorkshire (GB); Tomasz Witold LISKIEWICZ, Leeds, Yorkshire (GB); Anne NEVILLE, Leeds, Youdshire (GB)

(73) Assignee: University of Leeds, Leeds (GB)

(21) Appl. No.: 18/579,030

(22) PCT Filed: Jul. 12, 2022
(86) PCT No.: PCT/GB2022/051793

§ 371 Date: Jan. 12, 2024

(30) Foreign Application Priority Data
Jul. 12, 2021 (GB) 2110001.1
Apr. 20, 2022 (GB) 2205764.0

(51) Int. Cl. C23C 16/26; C23C 16/50; F16C 33/12

(52) U.S. Cl. CPC C23C 16/26; C23C 16/50; F16C 33/121; F16C 2202/50; F16C 2206/04

(57) ABSTRACT

The invention relates to tribological composites comprising diamond-like carbon and carbonaceous multi-layered nanoparticulate, e.g. graphene nanoplatelets, and methods for their preparation.

This invention relates to tribological composites and methods for their preparation.

Certain mechanical components are notoriously difficult to lubricate due to high contact pressures and high environmental temperatures. The use of diamond-like carbon (DLC) to reduce friction and wear is known but improved performance is needed for certain applications.

DLC is a name attributed to a variety of amorphous carbon materials, with some containing hydrogen. DLCs can display promising tribological properties such as low friction and wear which can vary depending on the environment and the sp²/sp³ content.

Graphene nanoplatelets (GNP) are stacked layers of graphene held together by weak intermolecular forces. These layers under the right conditions can provide effective lubrication properties and high mechanical strength. The present invention explores the use of both DLC and carbonaceous multi-layered nanoparticulate, e.g. GNP, in tribological composites.

CN 112126906 discloses a method of preparing a graphene/diamond-like carbon lubricating film. The preparation method comprises preparing a hydrogen-doped diamond-like carbon film on a substrate followed by the deposition of graphene to obtain the graphene/diamond-like carbon lubricating film. This produces a layered material in which graphene is located on the outer surface of a layer of DLC.

### BRIEF SUMMARY OF THE DISCLOSURE

In a first aspect of the invention there is provided a composite material, the composite material comprising:
a substrate; and
a coating on the substrate, wherein the coating comprises diamond-like carbon (DLC) and carbonaceous multi-layered nanoparticulate (CMLN); wherein at least a portion of the CMLN is situated at the interface between the substrate and the coating.

The CMLN is at least partially encapsulated by the DLC. Typically, certain portions of the CMLN are in contact with the substrate and certain portions of the CMLN is in contact with the DLC. Some of the CMLN may be entirely encapsulated by the DLC. Some of the CMLN may be on the outer surface of the coating.

The CMLN is typically distributed in the DLC. However, it is not necessarily evenly distributed throughout the coating. The concentration of carbonaceous multi-layered nanoparticulate at the interface between the substrate and the coating will typically be higher than the concentration of carbonaceous multi-layered nanoparticulate at the external surface of the coating.

The inventors have found that a coating that comprises both DLC and CMLN has better tribological properties than DLC on its own. This is the case even where much of the CMLN is situated away from the outer surface of the coating.

Typically, a significant portion (e.g. >50%, >80% or >95% by weight) of the CMLN in the coating is in contact with the substrate. It may be that >80% of the CMLN in the coating is in contact with the substrate.

The CMLN may be in contact with <40% of the substrate or the portion of the substrate that is coated. The CMLN may be in contact with <15% of the substrate or the portion of the substrate that is coated. The CMLN may be in contact with <10% of the substrate or the portion of the substrate that is coated. The CMLN may be in contact with between 1-9% of the substrate or the portion of the substrate that is coated. Preferably, the CMLN is in contact with 3-7% of the substrate or the portion of the substrate that is coated. More preferably, the CMLN is in contact with 4-5% of the substrate or the portion of the substrate that is coated.

It may be that the whole of the surface of the substrate is coated. It may be that just a portion of the surface of the substrate is coated.

It may be that greater than 50% of the coating is DLC. It may be that greater than 80% of the coating is DLC. It may be that greater than 90% (e.g. greater than 95%, or greater than 98%) of the coating is DLC. It may be that greater than 99% of the coating is DLC. It may be that less than 50% (e.g. less than 40% or less than 25% of the coating is CMLN). It may be that less than 10% (e.g. less than 5%, or less than 2%) of the coating is CMLN. It may be that less than 1% of the coating is CMLN.

The diamond-like carbon may be amorphous hydrogenated carbon, amorphous carbon, tetrahedral amorphous carbon, hydrogenated tetrahedral amorphous carbon, or a combination thereof. Preferably, the DLC is amorphous hydrogenated carbon. It may be that the DLC is amorphous hydrogenated carbon wherein less than 50% (e.g. less than 40%, or less than 30%) of the amorphous hydrogenated carbon is hydrogenated. It may be that the DLC is amorphous hydrogenated carbon wherein less than 20% of the amorphous hydrogenated carbon is hydrogenated. It may be that the DLC is amorphous hydrogenated carbon wherein between than 30% and 5% of the amorphous hydrogenated carbon is hydrogenated. It may be that the DLC is amorphous hydrogenated carbon wherein between 20% and 10% of the amorphous hydrogenated carbon is hydrogenated.

The DLC may be from 30% to 80% sp² hybridised. The DLC may be from 40% to 70% sp² hybridised. Preferably, the DLC is from 45% to 65% sp² hybridised. More preferably, the DLC is from 50% to 60% sp² hybridised.

The DLC may be doped with other elements. For example, the DLC may be doped with an element selected from Si, F, W, Cr and Ag.

Typically, the CMLN is in the form of a plurality of flakes. Therefore, the coating of the composite material of the first aspect may comprise diamond-like carbon (DLC) and carbonaceous multi-layered nanoparticulate (CMLN) flakes dispersed throughout the DLC.

The average thickness of the CMLN may be from 2 to 15 nm, e.g. 2 to 12 nm. The average thickness of the CMLN may be from 2 to 10 nm, e.g. 5 to 10 nm. The average thickness of the CMLN may be from 6 to 8 nm. It may be that greater than 50% by weight (e.g. greater than 75% by weight, greater than 90% or greater than 98%) of the CLMN has a thickness in the range from 2 to 15 nm. It may be that greater than 50% by weight (e.g. greater than 75% by weight, greater than 90% or greater than 98%) of the CLMN has a thickness in the range from 2 to 10 nm.

The average diameter of the CMLN may be <30 μm, e.g. <25 μm. The average diameter of the CMLN may be <20 μm, e.g. <15 μm. The average diameter of the CMLN may be >0.1 μm. Typically, the average diameter of the CMLN is >1 μm. The average diameter of the CMLN may be from 1 to 10 μm. The average diameter of the CMLN may be from 2 to 7 μm. It may be that greater than 50% by weight (e.g. greater than 75% by weight, greater than 90% or greater than 98%) of the CLMN has a diameter of from 0.1 to 30 μm, e.g. 1 to 25 μm. It may be that greater than 50% by weight (e.g. greater than 75% by weight, greater than 90% or greater than 98%) of the CLMN has a diameter of from 1 to 20 μm, e.g. 1 to 15 μm. It may be that greater than 50% by weight (e.g. greater than 75% by weight, greater than 90% or greater than 98%) of the CLMN has a diameter of from 1 to 10 μm. It may be that greater than 50% by weight (e.g. greater than 75% by weight, greater than 90% or greater than 98%) of the CLMN has a diameter of from 2 to 7 μm.

The surface area of the CMLN may be <100 m²/g. The surface area of the CMLN may be from 10 to 70 m²/g. The surface area of the CMLN may be from 10 to 50 m²/g, e.g. 20 to 40 m²/g.

The carbonaceous multi-layered nanoparticulate may be graphene nanoplatelets (GNP). The definitions of CMLN specified above may therefore apply to GNP. A single molecular layer of graphene is one atom thick and can therefore be described as a single atomic layer (“layer”). Typically, the GNP will have an average thickness of <100 layers. The GNP may have an average thickness of <50 layers. The GNP may have an average thickness of 5 to 45 layers. The GNP may have an average thickness of 15 to 35 layers, e.g. 15 to 30 layers. The GNP may have an average thickness of 15 to 25 layers.

It may be that greater than 50% by weight (e.g. greater than 75% by weight, greater than 90% or greater than 98%) of the GNP are <100 layers thick. It may be that greater than 50% by weight (e.g. greater than 75% by weight, greater than 90% or greater than 98%) of the GNP are <50 layers thick. It may be that greater than 50% by weight (e.g. greater than 75% by weight, greater than 90% or greater than 98%) of the GNP are from 5 to 45 layers thick. It may be that greater than 50% by weight (e.g. greater than 75% by weight, greater than 90% or greater than 98%) of the GNP are from 15 to 35 layers thick. It may be that greater than 50% by weight (e.g. greater than 75% by weight, greater than 90% or greater than 98%) of the GNP are from 15 to 30 layers thick. It may be that greater than 50% by weight (e.g. greater than 75% by weight, greater than 90% or greater than 98%) of the GNP are from 15 to 25 layers thick.

In some embodiments the thickness of the coating is between 0.5 to 3.5 μm, e.g. 0.7 to 3.0 μm. Preferably, the thickness of the coating is between 0.9 to 1.5 μm.

The composite of the present invention may be used on or in or may form part of a mechanical component. Therefore, the substrate may be, or may comprise, a metal, e.g. iron. The substrate may be, or may comprise, a metal alloy, e.g. a ferrous alloy, an aluminium alloy, a nickel alloy, a copper alloy or a titanium alloy. The substrate may be, or may comprise, a ferrous alloy, e.g. steel. The substrate may be, or may comprise, carbon steel, low-alloy steel, tool steel, bearing steel, stainless steel or cast iron.

The substrate may be, or may comprise, a polymer, e.g. a thermoplastic polymer, a thermosetting polymer or an elastomer. The substrate may be, or may comprise ceramic, e.g. glass or clay. The substrate may be or may comprise silicon.

The substrate may comprise an interlayer at the interface of the substrate and the coating. This interlayer may help adhere the coating to the rest of the substrate. The interlayer may comprise chromium, tungsten, titanium or a mixture thereof. The interlayer may comprise a metal carbide or nitride. The interlayer may comprise a carbide or nitride of a metal selected from chromium, tungsten and titanium. The interlayer may comprise tungsten carbide. The interlayer may comprise titanium nitride. The interlayer may comprise metallic chromium or titanium.

The interlayer may itself comprise one or more layers. The interlayer may comprise a layer that is a metal (e.g. metallic chromium or titanium) and a layer that comprises a metal carbide or nitride (e.g. a carbide or nitride of a metal selected from chromium, tungsten and titanium). If present, a metal layer may have a thickness in the range 100 nm to 1 μm (e.g. 200 nm to 400 nm). The layer that comprises a metal carbide 5 or nitride may have a thickness in the range 300 nm to 4 μm, e.g. 500 nm to 2 μm.

Alternatively, the interlayer may comprise a mixture of a metal and a metal carbide or nitride in which the concentration of the metal is higher at the interface of the interlayer with the substrate than it is at the interface of the interlayer with the coating.

The interlayer may comprise tungsten carbide-doped DLC, e.g. tungsten carbide-doped amorphous hydrogenated carbon.

The total thickness of the interlayer will typically be in the range 500 nm to 5 μm, e.g. 800 nm to 2 μm.

Preferably, when the substrate comprises iron, e.g. when the substrate is steel, the substrate comprises an interlayer as defined above.

In a second aspect of the invention is provided a mechanical component comprising a composite material according to the first aspect of the invention. Mechanical components may include, but are not limited to, bearings, bushings, belts, pulleys, brakes, clutches, chains, sprockets, couplings, collars, shafts, camshafts, screws, rivets, bolts, nuts, clips, gears, bumpers, drawer slides, eye nuts, eyebolts, support arms, grommets, hoist rings, hooks, casters, handles, pulls, and springs. The mechanical component may be a bearing or a camshaft. The mechanical component may be a bearing, e.g. a steel bearing. The mechanical component may be a camshaft, e.g. a steel camshaft.

In a third aspect of the invention is provided a method for preparing a composite material, the method comprising step a) and step b):
a) depositing carbonaceous multi-layered nanoparticulate (CMLN) onto a surface of a substrate to form a CMLN-deposited surface; and
b) depositing diamond-like carbon (DLC) onto the CMLN-deposited surface to form the composite material.

Step a) may be achieved by spin-coating a suspension of the carbonaceous multi-layered nanoparticulate. The spin-coating may be drop cast spin-coating.

Step a) may be achieved by spray-coating a suspension of the carbonaceous multi-layered nanoparticulate. Spray-coating (also known as spray deposition) is a method well known in the art. Step a) may therefore comprise positioning the surface of the substrate at a predetermined distance away from a spray coater and spraying the surface of the substrate with a suspension of the CMLN from the spray coater. Spray-coating allows CMLN to be deposited onto a surface of multiple substrate samples in quick succession. Step a) may therefore comprise:
holding at least two substrate samples in a rotatable sample holder so that a surface of each sample is exposed;
placing the sample holder at a predetermined distance away from a spray coater so that the exposed surfaces of the substrates face the spray coater;
rotating the sample holder, e.g. at between 50 and 70 rpm, e.g. between 55 and 65 rpm; and
spraying the exposed surfaces of the substrate samples with a suspension of CMLN from the spray coater, e.g. for a duration of <10 seconds, e.g. for 4 to 8 seconds.

In these embodiments the predetermined distance may be between 10 and 20 cm, e.g. between 13 and 18 cm. The CMLN suspension may be sprayed from the spray coater at a pressure of around 1 Barr. The spray coater may comprise an opening through which the CMLN suspension is sprayed, the opening having a diameter of from 0.6 to 1 mm.

The concentration of the carbonaceous multi-layered nanoparticulate in the suspension may be from 0.1 to 3 mg/ml. The concentration of the carbonaceous multi-layered nanoparticulate in the solvent may be from 0.2 to 2.5 mg/ml, e.g. 0.25 to 2 mg/ml. The concentration of the carbonaceous multi-layered nanoparticulate in the solvent may be from 0.5 to 1.5 mg/ml, e.g. 0.7 to 1.2 mg/ml. The suspension may comprise a solvent, e.g. N-Methyl-2-pyrrolidone (NMP) or isopropanol. Step a) may therefore further include:
i) suspending carbonaceous multi-layered nanoparticulate in a solvent, e.g. NMP or isopropanol.
   Ultra-sonication may be used to help suspend the carbonaceous multi-layered nanoparticulate in the solvent. The ultra-sonication may be carried out for 1-10 h, e.g. 4-8 h.

Step a) may be achieved by chemical vapour deposition (CVD), e.g. plasma enhanced chemical vapour deposition (PECVD).

The deposited carbonaceous multi-layered nanoparticulate may cover <40% of the surface or the portion of the surface to be coated. The deposited carbonaceous multi-layered nanoparticulate may cover <15% of the surface or the portion of the surface to be coated. The deposited carbonaceous multi-layered nanoparticulate may cover <10% of the surface or the portion of the surface to be coated. The deposited carbonaceous multi-layered nanoparticulate may cover between 1-9% of the surface or the portion of the surface to be coated. Preferably, the deposited carbonaceous multi-layered nanoparticulate covers 3-7% of the surface or the portion of the surface to be coated. More preferably, the deposited carbonaceous multi-layered nanoparticulate covers 4-5% of the surface or the portion of the surface to be coated.

After the carbonaceous multi-layered nanoparticulate has been deposited onto the surface of the substrate, the surface may be heat dried, e.g. at a temperature of from 100-200° C. The surface may be heat dried for 1-5 minutes.

Step a) may also further comprise:
iii) covering the CMLN-deposited surface with a thermally insulating material;
iv) heating the covered CMLN-deposited surface; and
v) removing the thermally insulating material from the CMLN-deposited surface.

The thermally insulating material may be a high-performance plastic or polymer. The thermally insulating material may be a polyimide film, e.g. 4,4′-oxydiphenylene-pyromellitimide film (Kapton®). The thermally insulating material may polytetrafluoroethylene (PTFE). Pressure may be applied to the insulating material once the surface is covered (and before step iv)).

In step iv) the covered surface may be heated to a temperature(s) of from 150 to 350° C., e.g. 150 to 300° C. The covered surface may be heated for 1 to 5 h, e.g. 2 to 4 h. After removing the thermally insulating material from the surface the substrate may be sonicated in a solvent, e.g. acetone or heptane. The solvent may acetone. The solvent may heptane. After removing the thermally insulating material from the surface area the substrate may be sonicated in a first solvent, e.g. acetone, and then sonicated in a second solvent, e.g. heptane.

Step b) may be achieved by chemical vapour deposition (CVD), e.g. plasma enhanced chemical vapour deposition (PECVD). The PECVD may be carried out at a temperature(s) from 150 to 350° C., e.g. 150 to 300° C. Acetylene gas may be used in the PECVD.

Step b) may be achieved by co-depositing diamond-like carbon (DLC) along with a metal or semimetal onto the CMLN-deposited surface to form the composite material. The co-deposition may be electrolytic co-deposition. The metal may be a transition metal, e.g. W or Cr.

It may be that steps a) and b) are carried out sequentially, i.e. by carrying out step a) and then step b). It may be that steps a) and b) are carried out simultaneously. This could be achieved by depositing CMLN onto the surface by PECVD and depositing the DLC by PECVD at the same time.

The substrate, carbonaceous multi-layered nanoparticulate and diamond-like carbon may be as defined above. The method of the third aspect may be a method for preparing a composite material according to the first aspect of the invention.

### BRIEF DESCRIPTION OF THE DRAWINGS

Embodiments of the invention are further described hereinafter with reference to the accompanying drawings, in which:

FIG. 1—Schematic flow diagram for the creation of DLC-GNP composites; (a) The HSS steel coupon with the interlayer, (b) the 1 minute drop cast spin coating process completed at 1000 rpm using 1 ml of GNP-NMP solution, (c) application of Kapton® tape pressed onto the surface and heated in an oven for 3 hours at 200° C., (d) removal of the tape and cleaned to remove NMP residue by ultra-sonication in acetone and then heptane, (e) deposition of DLC by PECVD for 90 minutes and, (f) the resultant DLC-GNP film along with cross-section showing the structure.

FIG. 2—Optical image showing the (A) GNP islands identified within the DLC-GNP 2 mg/ml sample and (B) the DLC-GNP samples derived from the GNP/NMP concentrations used.

FIG. 3—The coverage achieved using the spin coating method for the various concentrations of GNP/NMP solution.

FIG. 4—SEM cross-section of (a) pure DLC and (b) DLC-GNP 4.5% composite. The DLC, HSS, interlayer and GNPs are labelled. The thin layer above the DLC is a protective platinum film used in the FIB cross-sectioning process.

FIG. 5—Schematic cross-section diagram for the reciprocating pin on flat tribometer tests.

FIG. 6—WLI images of the surfaces of (a) pure DLC, (b) DLC-GNP 4.5% and (c) DLC-GNP 9.15%.

FIG. 7—SEM surface images of (a) pure DLC, (b) 1.16%, (c) 1.29%, (d) 4.28%, (e) 4.5%, (f) 8.97% and (g) 9.15% DLC-GNP samples.

FIG. 8—SEM wear track images of (a) pure DLC, (b) DLC-GNP 4.5% coverage and (c) DLC-GNP 9.15% coverage. The red circle in (c) is shown in (d).

FIG. 9—The COF for the various DLC-GNP coverages for (a) 6-hour wear test, and (b) the mean experimental COF for the final 3 hours of the wear test, along with the calculated lower and linear band estimates using the rules of mixtures.

FIG. 10—Extended wear tests for DLC-GNP (4.5%) and pure DLC. The (a) first 6000 seconds shows a similar increase during the wearing-in process, and (b) the full 36,000 seconds has been split into three distinct zones.

FIG. 11—A typical load-unload curve used to calculate hardness (H) and elastic modulus (E) by applying an Oliver-Pharr analysis.

FIG. 12—Optical image showing the GNP islands identified within a DLC-GNP 1 mg/ml sample obtained via spray-coating deposition.

FIG. 13—The mean experimental COF of various samples over 6 hours and for the final 3 hours of the wear test. Method b is a spray coating method (1 mg/ml GNP/isopropanol, 15 cm distance, 1 Barr pressure, 0.7 mm opening, rotation speed of 60 rpm, 6 seconds deposition time). Method a is a spin-coating method (1 mg/ml GNP/NMP, 1000 rpm for 1 min). For each pair of bars, the left bar depicts “Average 6 hours” and the right bar depicts “Average last 3 hours”.

### DETAILED DESCRIPTION

The term “surface” may refer to either a portion of a surface of the substrate or to the entirety of a surface of the substrate.

The term “interface” donates a surface forming a common boundary between two separate entities, e.g. between the substrate and the coating.

For the absence of doubt, when the substrate comprises an interlayer at the interface between the substrate and the coating, the interlayer is deemed to form part of the substrate.

The term ‘semimetal’ refers to chemical elements that have properties of both metals and nonmetals. Semimetals include B, Si, Ge, As, Sb, Te, Po and Ts.

Throughout the description and claims of this specification, the words “comprise”, “contain”, “involve” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

### EXAMPLES

Throughout this specification these abbreviations have the following meanings:

| | |
|---|---|
| A | ampere |
| CI | cast iron |
| COF | coefficient of friction |
| DLC | diamond-like carbon |
| FEGSEM | field emission gun scanning electron microscope |
| FIB | focused ion beam |
| GNP | graphene nanoplatelet |
| HSS | high-speed steel |
| NMP | N-Methyl-2-pyrrolidone |
| PAO | poly-alpha-olefin |
| PECVD | plasma enhanced chemical vapour deposition |
| Rₐ | surface roughness |
| Rₚ | maximum peak height |
| SCCM | standard cubic centimetres per minute |
| SEM | scanning electron microscope |
| V | voltage |
| WLI | white light interferometry |

### Synthesis of DLC-GNP Composite

The production of DLC-GNP composite films can be completed on a polished high-speed steel (HSS) coupon (6 mm thickness, 30 mm diameter) coated with an interlayer of Chromium/Tungsten-Carbide/Tungsten-DLC to aid adhesion. The surface roughness (Rₐ) of the HSS surfaces covered with the interlayer measured by white light interferometry (WLI) was between 10-20 nm.

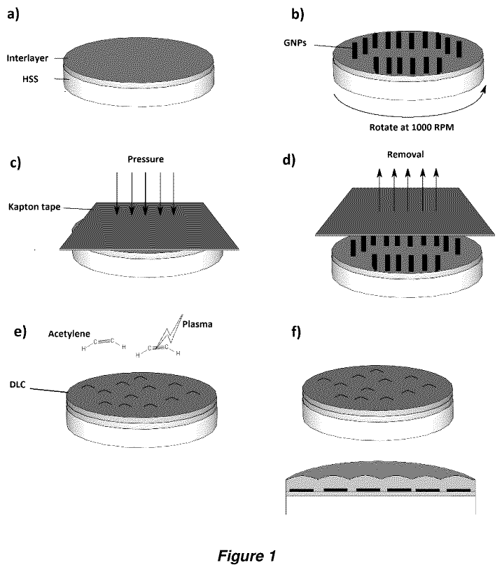

The GNPs were suspended in N-Methyl-2-pyrrolidone (NMP) by ultra-sonication for 6 hours prior to deposition at concentrations between 0.25 mg/ml-2 mg/ml. The GNPs purchased commercially from Sigma Aldrich had a typical surface area of 120 to 150 m²/g, average thickness of 6-8 nm and particle size of 5 μm. The GNP deposition process is completed in three essential steps, with a schematic workflow shown in FIG. 1. The steps are as follows:
1. Dispersing the GNPs onto the substrate (HSS coupon) by drop cast spin-coating 1 ml of GNP/NMP solution at 1000 rpm for 1 minute before drying the coated substrate on a plate heated at 150° C. for 2 minutes.
2. Heat treating the coated substrate by applying Kapton® tape to the dried surface of the coupon which is then pressed to remove any bubbles. The sample is then placed into a 200° C. oven for 3 hours, after which the tape is removed and the sample is placed into an ultrasonic bath of acetone for 5 minutes, followed by 5 minutes in heptane.
3. The deposition of the DLC is completed in a 200° C. heated chamber by plasma enhanced chemical vapour deposition (PECVD) using a Hauzer Flexicoat 850 system with acetylene used as the precursor gas. The conditions for the DLC deposition are shown in Table 1.

TABLE 1
Deposition parameters used to deposit DLC in
the Hauzer Flexicoat 850 system by PECVD.

| | | Argon Gas | C₂H₂ Gas | Bias | UBM Coil |
|---|---|---|---|---|---|
| | Time | flow | flow | DC | current |
| Process | (minutes) | (sccm) | (sccm) | (V) | (A) |
| Pumping | 60 | — | — | — | — |
| Plasma etch | 20 | 50 | — | −200 | — |
| a-C:H film | 90 | — | 340 | −740 | 4 |
| deposition | | | | | |

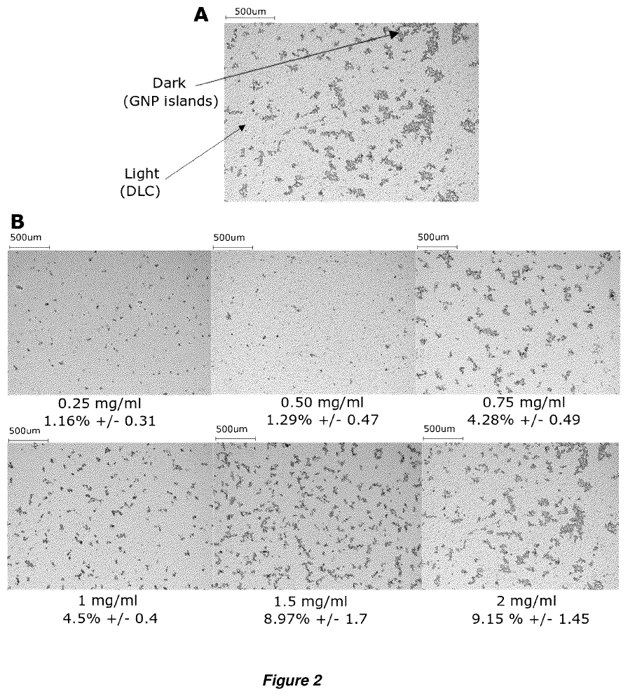

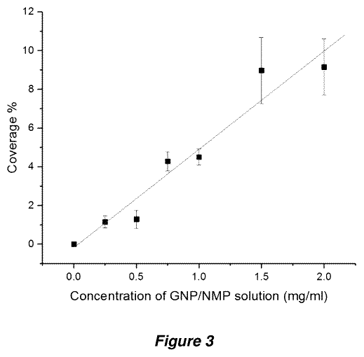

The GNP/NMP concentrations used were 0 mg/ml, 0.25 mg/ml, 0.5 mg/ml, 0.75 mg/ml, 1 mg/ml, 1.5 mg/ml and 2 mg/ml. The produced samples are shown in FIG. 2, with FIG. 3 displaying the % coverage achieved for the various GNP/NMP concentrations. The darkness of the GNP islands in FIG. 2 allows easy identification for contrast measurements using the ImageJ program.

### Sample Structures

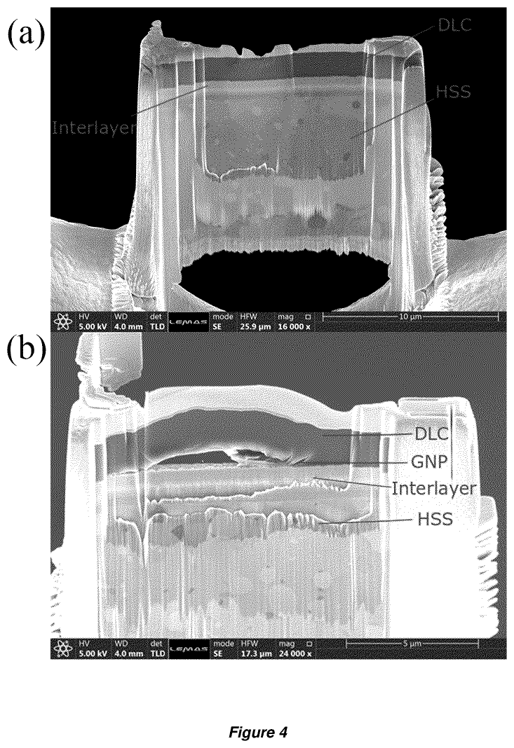

The thickness of the film was measured by cross-section and viewed using a FEI Helios G4 CX Dual Beam—High resolution mono-chromated FEGSEM with precise Focused Ion Beam (FIB). The working distance was 4 mm and accelerating voltage of 5 kV. The thickness was measured to be 1.27 μm. The cross section of pure DLC and DLC-GNP 4.5% is shown in FIG. 4. The DLC-GNP composite shown in FIG. 4 displays some removal from the interlayer under the GNPs which indicates the forces between the GNPs and the interlayer are weak compared to the forces at the interface between GNP and DLC where there are no gaps. This indicates some bonding between GNPs and DLC.

### Tribological Testing

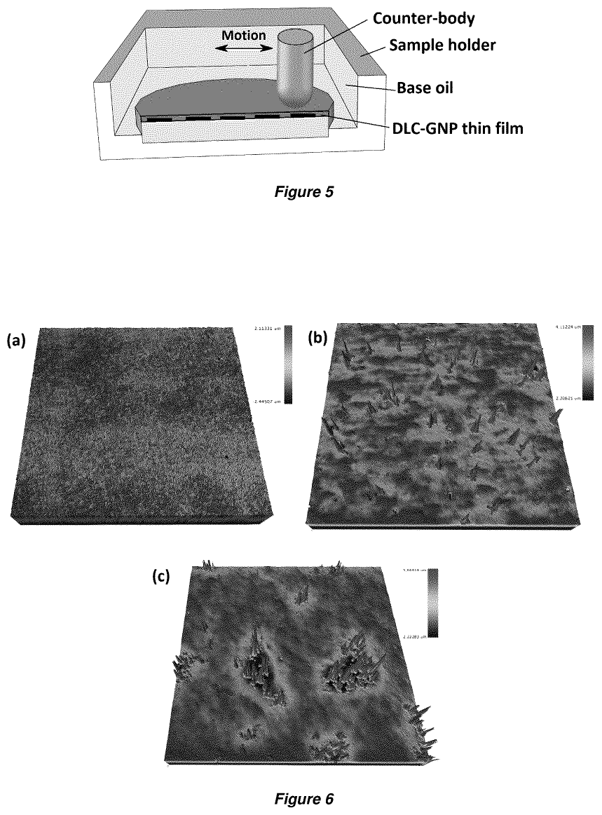

The tribological testing of the DLC-GNP composite was completed in oil lubricated conditions with a reciprocating pin-on-flat configuration. The measurements were made using a Biceri tribometer in a poly-alpha-olefin (PAO) base oil with no additives. A contact pressure of 750 MPa was used (comparable to that experienced in a demanding cam follower environment). Tests under the same contact pressure (750 MPa) but in an unlubricated environment were also completed for comparison. The test conditions are shown in Table 2. A schematic diagram of the test equipment is shown in FIG. 5.

TABLE 2
Test conditions used in lubricated wear tests
Test conditions

| Speed | 20 | mm/s |
|---|---|---|
| Contact pressure | 750 | MPa |
| Temperature | 100° | C. |
| Lubricant | PAO Group IV (η₀ 3.8 Pa s at 100° C.) | |
| Counter material | Cast iron (CI) 40 mm radius | |
| Test durations | 6 | hours |

The material properties are shown in Table 3. A cast iron counter body was used as a typical material used in an engine. The PAO base oil without any additives was used at a working temperature of 100° C. The Lambda ratio (λ) can be calculated using the Hamrock-Dowson equation to be 0.001 which is well into the boundary lubrication regime.

TABLE 3
Material properties for the substrate, coating and counter
material used in the wear tests. The surface roughness
measurements were calculated using WLI, with the Young's
modulus calculated using nano-indentation.

| | Substrate | | Coating | | Counter body | |
|---|---|---|---|---|---|---|
| Material | M2 HSS | | Pure DLC | | Cast iron | |
| Roughness (Rₐ) | 10-20 | nm | 21-112 | nm | 250-313 | nm |
| Elastic modulus | 210 | GPa | 203 | GPa | 170 | GPa |

| | | | |
|---|---|---|---|
| Poisson's ratio | 0.27 | 0.2 | 0.26 |
| Dimensions | 15 mm diameter | 1.27 μm | 20 mm length |
| | 6 mm thickness | thickness | 40 mm radius |
| | | | head |

The wear for both the DLC-GNP samples and counter body was calculated using the Archard wear equation:

$$\\ \begin{matrix}{K}_{i} = \frac{{V}_{i}}{F \times S} , & ( 1 )\end{matrix}$$

where Kᵢ is the dimensional wear coefficient, index i is the surface considered, F is the normal load (N), S is the sliding distance (mm) and Vᵢ is the wear volume (mm³).

The wear volume for the samples was completed using WLI which calculates the volume removed from the wear scar. The wear volume from the counter body is calculated from the lost section of the sphere from the wear scar diameter of the CI counter body using optical microscopy.

### Nano-Indentation: Elastic Modulus and Hardness

A nano-indenter records load and displacement changes in UN and sub-nanometre scales during indentation of a μm sized tip into a sample surface. To calculate the elastic modulus (E) and hardness (H) of the of the DLC-GNP composites, a total of 100 indentations were undertaken using a Berkovich diamond indenter in a Micromaterials Nanotest Nanotester. Each indent had a 25 μm space between each indent and depth controlled to a maximum of no more than 10% of the sample thickness (<100 nm). The load and unload time for each indentation step was 6 s. A 1 s dwell was used at the maximum load to ensure there was no creep. A 60 s dwell period in the final unload step was used for thermal drift correction.

### Characterisation

Optical images of the DLC-GNP composite were taken using a Lecia 800M optical microscope, with the 5× optical zoom lens with a numerical aperture of 0.7. The GNP island coverage was measured using ImageJ freeware software using the colour threshold of the dark islands to calculate the coverage percentage. Five random areas were measured with the standard deviation taken. Scanning electron microscope (SEM) images of the sample surface and wear scar were taken using the Carl Zeiss EVO MA15 SEM.

Surface measurements were taken using a Bruker NPFlex 3D optical profiler using a 50× objective lens with a vertical resolution of <0.15 nm measuring surface roughness and wear profiles. Measurements were taken from five random spots on each sample and analysed using the Vison64 software package. The range of the surface roughness values is given.

### Results

### Surface Analysis

The surface roughness (Rₐ) and maximum peak height (Rₚ) measurements were taken at five different sections. Averages values are calculated as shown in Table 4, and WLI images are displayed in FIG. 6.

TABLE 4
Surface roughness measurements for DLC-
GNP samples of various GNP % coverages.

| Sample | Rₐ (nm) | Rₚ (nm) |
|---|---|---|
| Pure DLC | 21 ± 1 | 653 ± 215 |
| DLC-GNP 1.16% | 33 ± 13 | 3030 ± 840 |
| DLC-GNP 1.29% | 49 ± 2 | 2576 ± 1252 |
| DLC-GNP 4.28% | 46 ± 7 | 4089 ± 650 |
| DLC-GNP 4.5% | 77 ± 6 | 5550 ± 1961 |
| DLC-GNP 8.9% | 85 ± 23 | 51984 ± 1405 |
| DLC-GNP 9.15% | 112 ± 49 | 50732 ± 662 |

The surface roughness increases as the GNP coverage increases. The maximum peak height measurements coverages greater than 4.5% show an almost 10 times increase to the sample coverages of 4.5% or lower.

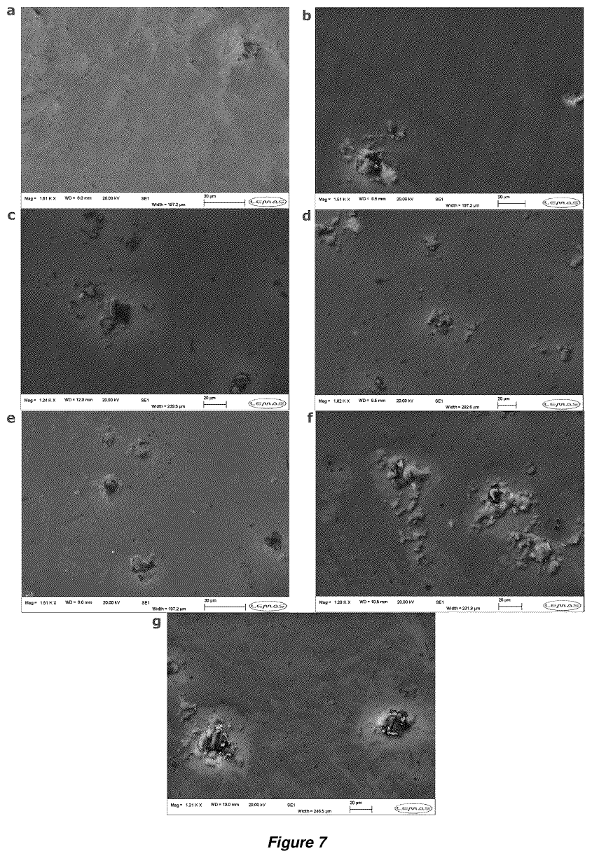

The surfaces were viewed by SEM before and after wear, as shown in FIG. 7. The pure DLC sample is as smooth as traditionally expected from samples produced by PECVD, but as the coverage of GNPs increases the surface displays more features. The GNPs are covered by a thin layer of DLC at coverage values of <9.15%, but above this, images show some of the GNPs may be protruding from the surface.

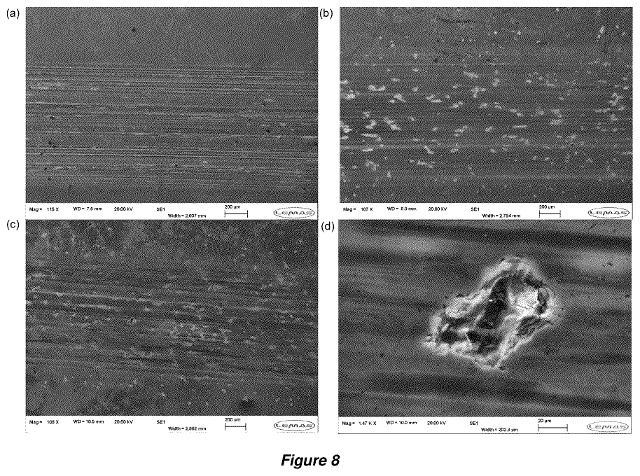

The worn surfaces were viewed by SEM and the two highest coverages (8.97% and 9.15%) display removal of GNPs within the wear track (FIG. 8). The pure DLC shows a considerable amount of damage from both abrasive and adhesive wear. Wear tracks of DLC-GNP 4.5% show more of a polishing effect with reduced adhesive wear. The GNP islands also remain in place.

The SEM images show that the GNP islands in DLC-GNP 9.15% can be removed by wear. This type of removal through to the interlayer is detrimental, and over longer periods of time will lead to complete delamination to the rest of the DLC film.

### Friction and Wear

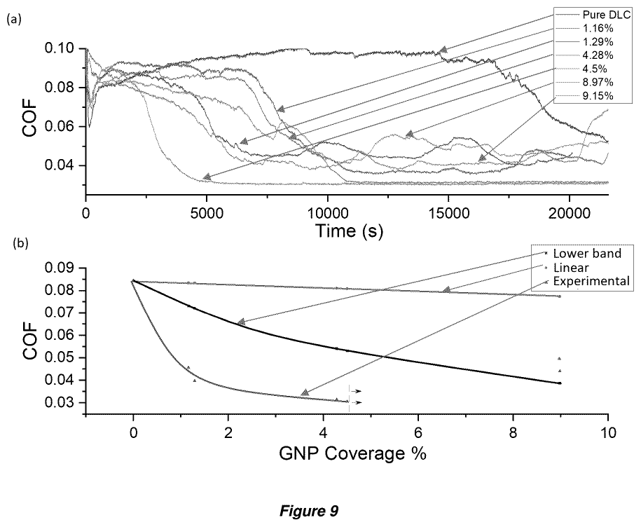

The wear tests completed in base-oil lubricated environments displayed favourable results as shown in FIG. 9. The best performing sample based purely on the frictional response is the 4.5% coverage with the 4.28% being a close second. The samples with high coverage values of 8.97% & 9.15% display friction reduction but the values are unsteady, with the 9.15% increasing dramatically at around 20,000 seconds. The DLC-GNP of 1.15% and 1.29% coverage showed that the inclusion of a small amount of GNPs decreases the COF, but not as effectively as both the DLC-GNP 4.28% & 4.5% films.

The average COF for the final 3 hours along with the calculations based on the upper and linear band simple rules of mixtures for composite materials is shown in FIG. 9. The equations used for the rules of mixtures are:

$$\\ \begin{matrix}Lower band estimates : {μ}_{( total )} = \frac{1}{\frac{{C}_{GNP}}{{μ}_{GNP}} + \frac{1 - {C}_{GNP}}{{μ}_{DLC}}} ; and & ( 2 )\end{matrix}$$

$$\\ \begin{matrix}Upper linear band estimates : {μ}_{( total )} = ( {C}_{GNP} \times {μ}_{GNP} ) + ( 1 - {C}_{GNP} ) \times {μ}_{DLC} , & ( 3 )\end{matrix}$$

with C_{GNP} being the coverage of GNP. The μ_{(DLC)} is taken as the mean value from the final 3 hours of friction, and μ_{(GNP)} taken to be 0.006. The results show a similar friction reduction trend as predicted mathematically but at the lowest experimental point the lower-band estimate is almost double. The experimental results show an increase in frictional values above 4.5%.

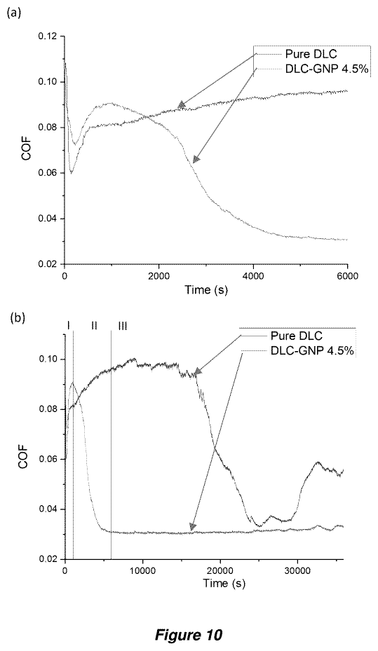

The pure DLC sample displayed a reduction in friction towards the end of the test so was left to run for 20 hours, as shown in FIG. 10, to determine if the performance improved over time. This was not the case. The DLC-GNP 4.5% coverage was also tested for an extended wear test and displayed a steady low COF which was maintained without failure.

### Elastic Modulus and Hardness

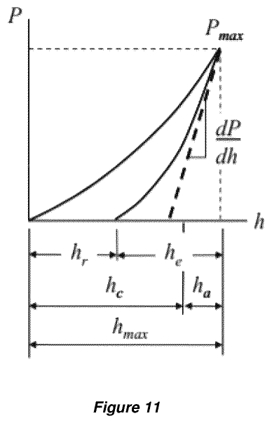

The load and unload curve is used to calculate the Hardness (H) and elastic modulus (E) by applying an Oliver-Pharr analysis. A typical load-unload curve can be seen in FIG. 11, where:
Pₘₐₓ—Maximum load.
hₘₐₓ—Maximum depth beneath the specimen free surface.
h_{c}—Depth of the contact circle.
hₐ—Depth of contact circle measured from the specimen free surface.
hᵣ—Depth of the residual impression.
hₑ—Displacement associated with elastic recovery during unloading
dP/dh—Unloading stiffness (S)

The unloading stiffness can be used to calculate the reduced elastic modulus Eᵣ using the equation:

$$\\ S = \frac{dP}{dh} = \frac{2}{\sqrt{π}} {E}_{r} \sqrt{A}$$

Where A is the projected indentation area.

The reduced elastic modulus is a function of the elastic modulus (Eᵢ) and poision ratio (Vᵢ) of the indenter and that of the elastic modulus (Eₛ) and poision ratio (Vₛ) of the sample using the equation:

$$\\ \frac{1}{{E}_{r}} = \frac{( 1 - {V}_{s} )}{{E}_{s}} + \frac{( 1 - {V}_{i} )}{{E}_{i}}$$

The area function of the indenter was found by indentation into a fused silica reference sample. Hardness (H) and elastic modulus (E) were calculated by applying Oliver-Pharr analysis. Eₛ and Vₛ (0.3) are Young's modulus and Poisson's ratio for the coating; Ei (1140 GPa) and Vi (0.07) are the same quantities for diamond respectively. The hardness was calculated from the equation:

$$\\ H = \frac{{P}_{max}}{A}$$

The Elastic Modulus calculated from the reduced elastic modulus and hardness calculated for all the DLC-GNP samples is shown in Table 5.

TABLE 5
Calculated elastic modulus for DLC-GNP
samples of various GNP % coverages.

| Sample | Elastic Modulus (GPa) | Hardness (GPa) |
|---|---|---|
| Pure DLC | 203.4 | 23.76 |
| DLC-GNP 1.16% | 201 | 22.99 |
| DLC-GNP 1.29% | 195 | 22.7 |
| DLC-GNP 4.28% | 192 | 22.1 |
| DLC-GNP 4.5% | 187.3 | 21.81 |
| DLC-GNP 8.9% | 180 | 21.69 |
| DLC-GNP 9.15% | 172 | 21.23 |

### Spray Coating

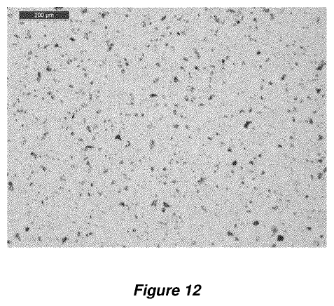

DLC-GNP composites were prepared according to the three steps discussed above, except that step 1 included depositing the GNPs onto the substrate (HSS coupon) by spray-coating a 1 mg/ml GNP/isopropanol suspension at distance of 15 cm, under 1 Barr pressure through a 0.7 mm opening at a rotation speed of 60 rpm for 6 minutes. The coated substrate also does not need to be dried on a hotplate in step 1. The coverage achieved using this spray-coating method can be seen in FIG. 12.

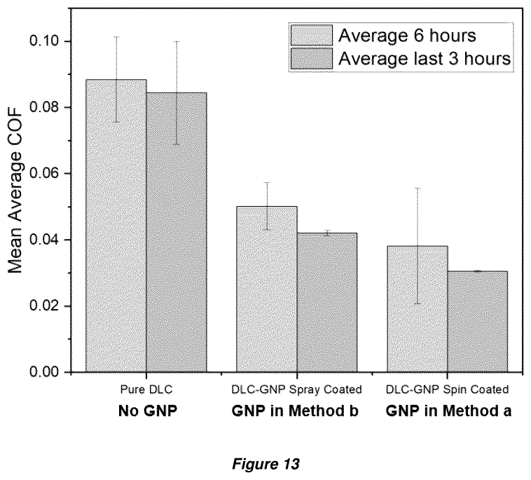

DLC-GNP composites made according to this method were subject to the wear test described above. The mean average COF of DLC-GNP composites made according to this method can be seen in FIG. 13 along with the mean average COF of pure DLC composites and DLC-GNP composites made according to the 1 mg/ml spin-coating method outlined above.

As can be seen in FIG. 13, the composite of the invention that was formed by spray coating the GLP performs well with clear advantages over pure DLC. Although it is slightly behind the values achieved by DLC-GNP composites prepared by spin coating, spray-coating provides a more cost effective and commercially friendly alternative deposition technique.

1. A composite material, the composite material comprising:
a substrate; and
a coating on the substrate, wherein the coating comprises diamond-like carbon (DLC) and carbonaceous multi-layered nanoparticulate (CMLN); wherein at least a portion of the CMLN is situated at the interface between the coating and the substrate.

2. The composite material of claim 1, wherein the concentration of CMLN at the interface between the substrate and the coating is higher than the concentration of CMLN at the external surface of the coating.

3. The composite material of claim 1 or claim 2, wherein the CMLN is in contact with 4-5% of the substrate or the portion of the substrate that is coated.

4. The composite material of any preceding claim, wherein the CMLN is graphene nanoplatelets.

5. The composite material of any preceding claim, wherein the average thickness of the CMLN is between 2-10 nm.

6. The composite material of any preceding claim, wherein the thickness of the coating is between 0.9-1.5 μm.

7. The composite material of any preceding claim, wherein the DLC comprises amorphous hydrogenated carbon.

8. The composite material of any preceding claim, wherein the substrate comprises metal.

9. The composite material of any preceding claim, wherein the substrate is steel.

10. The composite material of any preceding claim, wherein the substrate comprises an interlayer at the interface between the substrate and the coating.

11. The composite material of claim 10, wherein the interlayer comprises a carbide or nitride of a metal selected from chromium, tungsten and titanium.

12. The composite material of claim 10 or claim 11, wherein the interlayer comprises metallic chromium or titanium.

13. The composite material of any one of claims 10 to 12, wherein the interlayer is between 500 nm and 5 μm thick.

14. A mechanical component comprising a composite material according to any preceding claim, wherein the mechanical component is a bearing or a camshaft.

15. A method for preparing a composite material, the method comprising step a) and step b):
a) depositing carbonaceous multi-layered nanoparticulate (CMLN) onto a surface of a substrate to form a CMLN-deposited surface; and
b) depositing diamond-like carbon (DLC) onto the CMLN-deposited surface to form the composite material.

16. The method of claim 15, wherein the deposited CMLN covers 4-5% of the surface area.

17. The method of claim of claim 15 or 16, wherein step a) is achieved by spin-coating a suspension of CMLN.

18. The method of claim 17, wherein the concentration of the CMLN in the suspension is 0.7 to 1.2 mg/ml.

19. The method of any one of claims 15 to 18, wherein step a) further comprises:
covering the CMLN-deposited surface with a thermally insulating material;
heating the covered CMLN-deposited surface; and
removing the thermally insulating material from the CMLN-deposited surface.

20. The method of any of claims 15 to 19, wherein step b) is achieved by plasma enhanced chemical vapour deposition (PECVD).

21. The method of any one of claims 15 to 20, wherein the CMLN is graphene nanoplatelets.

22. The method any one of claims 15 to 21, wherein the DLC comprises amorphous hydrogenated carbon.

23. The method of any one of claims 15 to 22, wherein the substrate is steel.

24. The method of claim 15, wherein the composite material is a composite material according to any one of claims 1 to 13.

25. A composite material obtained by the process of any one of claims 15 to 23.
